(19) United States
(12) Patent Application Publication
(10) Pub. No.: US 2026/0302702 A1
(43) Pub. Date: Oct. 1, 2026

(54) HEAT-DISSIPATING STRUCTURE

(71) Applicant: Resonac Corporation, Tokyo (JP)

(72) Inventors: Yui YAMAGUCHI, Minato-ku, Tokyo (JP); Takahiro YAMASHITA, Minato-ku, Tokyo (JP); Kazutake FUJISAWA, Minato-ku, Tokyo (JP); Seiichi ITO, Minato-ku, Tokyo (JP); Hiroaki SHODA, Minato-ku, Tokyo (JP); Yuji FUKUKAWA, Minato-ku, Tokyo (JP); Dai TSUNODA, Minato-ku, Tokyo (JP)

(21) Appl. No.: 19/480,169

(22) PCT Filed: Sep. 24, 2024
(86) PCT No.: PCT/JP2024/033998

§ 371 Date: Oct. 30, 2025

(30) Foreign Application Priority Data
Sep. 26, 2023 (JP) 2023-163697

(51) Int. Cl. H01R 25/16; H05K 7/20

(52) U.S. Cl. CPC H01R 25/161; H05K 7/20436

(57) ABSTRACT

A heat-dissipating structure includes a conductive member; and a cooling and heating member, in which an adhesive layer and an insulating layer are provided between the conductive member and the cooling and heating member.

### TECHNICAL FIELD

The present disclosure relates to a heat-dissipating structure.

### BACKGROUND ART

A vehicle equipped with a motor, such as a hybrid vehicle or an electric vehicle, is provided with a drive means for driving the motor. The drive means is composed of a power module having a plurality of power semiconductors such as an IGBT (Insulated Gate Bipolar Transistor), electronic components such as capacitors, and a bus bar that electrically connects these electronic components.

When driving the motor, a large current may flow through the bus bar that joins the power semiconductors, capacitors, and other electronic components. In a case in which a large current flows through the bus bar, the drive means generates heat due to switching loss, resistance loss and the like, and therefore it is necessary to efficiently cool the drive means.

As a cooling means for cooling the drive means, a heat sink made of a metal such as aluminum (Al) or copper (Cu) is used because of its high thermal conductivity (for example, see Patent Document 1).

Further, Patent Document 2 describes that a heat sink and a heat-generating element are bonded via an insulating adhesive layer.

### PRIOR ART DOCUMENTS

### Patent Documents

Patent Document 1: Japanese Patent Application Laid-Open (JP-A) No. 2010-182831
Patent Document 2: JP-A No. 2009-135524

### SUMMARY OF INVENTION

In a case in which a heat sink is mounted on a vehicle or the like, the heat sink is required to be thinned.

Since the cooling member such as a heat sink is often made of a metal from the viewpoint of heat dissipation, it is necessary to insulate between the conductive member and the cooling member. Therefore, from the viewpoint of ensuring insulation, it has been difficult to reduce the distance from the conductive member to the cooling member and to make the structure thinner. It should be noted that in a case in which the distance from the conductive member to the cooling member is reduced, the heat dissipation property also tends to improve.

Accordingly, the present disclosure is intended to provide a heat-dissipating structure capable of reducing a distance from the conductive member to the cooling member.

### Solution to Problem

The present disclosure includes the following aspects.

<1> A heat-dissipating structure, including a conductive member; and a cooling and heating member,
in which an adhesive layer and an insulating layer are provided between the conductive member and the cooling and heating member.
   <2> The heat-dissipating structure according to <1>, in which an area of the insulating layer is larger than an area of an adhesion surface of the conductive member or an area of an adhesion surface of the cooling and heating member.
   <3> The heat-dissipating structure according to <1> or <2>, in which the adhesive layer, the insulating layer, and the adhesive layer are disposed in this order from a side of the conductive member.
   <4> The heat-dissipating structure according to any one of <1> to <3>, in which:
at least one of the conductive member or the cooling and heating member contacts the insulating layer; and
the insulating layer covers a corner portion of the at least one of the conductive member or the cooling and heating member.
   <5> The heat-dissipating structure according to <4>, in which the insulating layer and the adhesive layer are disposed in this order from a side of the conductive member.
   <6> The heat-dissipating structure according to <4>, in which the adhesive layer and the insulating layer are disposed in this order from a side of the conductive member.
   <7> The heat-dissipating structure according to any one of <1> to <6>, in which a distance between the conductive member and the cooling and heating member is 500 μm or less.
   <8> The heat-dissipating structure according to any one of <1> to <7>, in which the conductive member includes at least one selected from the group consisting of a bus bar and a terminal for fastening the bus bar.

### Advantageous Effects of Invention

According to the present disclosure, it is possible to provide a heat-dissipating structure capable of reducing a distance from the conductive member to the cooling member.

### BRIEF DESCRIPTION OF DRAWINGS

FIG. 1 is a schematic perspective view showing a part of a housing for disposing a heat-generating element such as a semiconductor element, and illustrates an example in which a heat-dissipating structure, as an example of the heat-dissipating structure in the present disclosure, is incorporated into a housing.

FIG. 2 is a schematic cross-sectional view showing an example of a cross-sectional structure of the heat-dissipating structure in the present disclosure.

FIG. 3 is a schematic cross-sectional view showing another example of a cross-sectional structure of the heat-dissipating structure in the present disclosure.

FIG. 4 is a schematic cross-sectional view showing another example of a cross-sectional structure of the heat-dissipating structure in the present disclosure.

FIG. 5 is a schematic cross-sectional view showing another example of a cross-sectional structure of the heat-dissipating structure in the present disclosure.

FIG. 6 is a schematic cross-sectional view showing another example of a cross-sectional structure of the heat-dissipating structure in the present disclosure.

FIG. 7 is a schematic cross-sectional view showing another example of a cross-sectional structure of the heat-dissipating structure in the present disclosure.

FIG. 8 is a schematic perspective view of a heat-dissipating terminal block 100 as an example of the additional heat-dissipating terminal block.

FIG. 9 is a schematic cross-sectional view showing an example of a cross-sectional structure around a bolt 21.

FIG. 10 is a schematic cross-sectional view showing another example of a cross-sectional structure around a bolt 21.

FIG. 11 is a schematic cross-sectional view showing another example of a cross-sectional structure around a bolt 21.

FIG. 12 is a schematic cross-sectional view showing another example of a cross-sectional structure around a bolt 21.

FIG. 13 is a schematic cross-sectional view showing another example of a cross-sectional structure around a bolt 21.

FIG. 14 is a schematic cross-sectional view showing another example of a cross-sectional structure around a bolt 21.

FIG. 15 is a diagram for explaining a producing example of a heat-dissipating terminal block having the cross-sectional structure shown in FIG. 9.

FIG. 16 is a diagram for explaining a producing example of a heat-dissipating terminal block having the cross-sectional structure shown in FIG. 11.

FIG. 17 is a diagram for explaining a producing example of a heat-dissipating terminal block having the cross-sectional structure shown in FIG. 12.

FIG. 18 is a diagram for explaining a producing example of a heat-dissipating terminal block having the cross-sectional structure shown in FIG. 13.

FIG. 19 is a schematic cross-sectional view showing an example of a heat-dissipating terminal block having a shoulder bolt.

### DESCRIPTION OF EMBODIMENTS

Hereinafter, embodiments in the present invention will be described in detail. However, the present invention is not limited to the following embodiments. In the following embodiments, the components (including elemental steps, or the like.) are not essential unless otherwise specified. The same applies to the numerical values and their ranges, and they do not limit the present invention.

In the present specification, in a case in which a numerical range is indicated using “to”, the numerical values before and after “to” are included as the minimum and maximum values, respectively.

In the present invention, in the numerical ranges described in stepwise, the upper limit or lower limit value described in a certain numerical range can also be replaced with the upper limit or lower limit value of another numerical range described in stepwise. In the numerical ranges described in the present disclosure, the upper or lower limit value of the numerical range may be replaced by the value shown in each example.

In the present disclosure, each component may contain two or more types of corresponding substances. In a case in which a composition contains two or more substances corresponding to each component, a content or amount of each component means a total content or amount of the two or more substances present in the composition, unless otherwise specified.

In the present disclosure, particles corresponding to each component may include multiple types of particles. In a case in which multiple types of particles corresponding to each component are present in the composition, a particle size of each component means a value for a mixture of the multiple types of particles present in the composition, unless otherwise specified.

In the present disclosure, the vertical direction refers to the vertical direction in the drawings, and the device may also be used upside down. The vertical direction may also be replaced with a lateral direction. In the present disclosure, the surface side on which the conductive member is fastened is described as an upper surface, and the opposite surface is described as a lower surface.

### <Heat-Dissipating Structure>

A heat-dissipating structure in the present disclosure includes a conductive member; and a cooling and heating member, in which an adhesive layer and an insulating layer are provided between the conductive member and the cooling and heating member.

The reason why it is possible in the heat-dissipating structure in the present disclosure to reduce a distance from the conductive member to the cooling member is presumed to be as follows.

In the heat-dissipating structure in the present disclosure, the insulating adhesive layer provided between the conductive member and the cooling member is functionally separated into an insulating layer and an adhesive layer.

As a result, an insulating layer specialized in insulation performance can be provided, and an adhesive layer specialized in adhesion can be provided, making it possible to reduce the thickness of each layer. Consequently, the distance from the conductive layer to the heat dissipation layer can be reduced, and heat dissipation performance can be enhanced.

By functionally separating the insulating layer and the adhesive layer, it is also possible, as a secondary effect, to make the area of the insulating layer larger than the area of a bonding surface of the conductive member or a bonding surface of the cooling member. This can further enhance the insulation performance. Along with this, it is also possible to increase the area of the bonding surface of the conductive member or the bonding surface of the cooling member, thereby further improving the heat dissipation performance.

Hereinafter, specific examples of the heat-dissipating structure in the present disclosure will be described with reference to the drawings, but the embodiment is not limited thereto. In addition, the sizes of the members in each drawing are conceptual, and the relative size relationship between the members is not limited thereto.

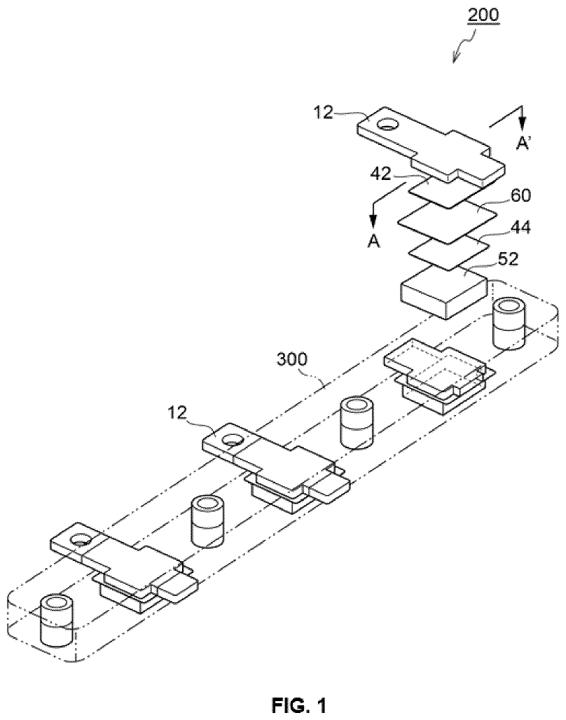

FIG. 1 is a schematic perspective view showing a part of a housing for disposing a heat-generating element (a member to be cooled) such as a semiconductor element, and shows an example in which a heat-dissipating structure 200, as an example of the heat-dissipating structure in the present disclosure, is incorporated into a housing 300. FIG. 1 shows an exploded view of the heat-dissipating structure 200.

In the housing shown in FIG. 1, a cooling member 52 such as a heat spreader is disposed under a O-bus bar 12 connected to a semiconductor element, and between the O-bus bar 12 and the cooling member 52, adhesive layer 42, insulating layer 60, and adhesive layer 44 are provided in this order.

In the housing of FIG. 1, although the cooling member 52 is disposed under the O-bus bar 12, a conductive member other than the O-bus bar may also be used. A shape of the housing and an arrangement of the members are not limited thereto.

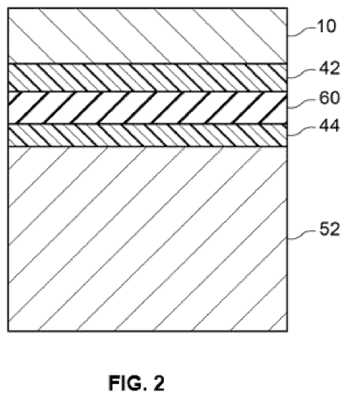

FIG. 2 is a schematic cross-sectional view showing an example of the cross-sectional structure of the heat-dissipating structure in the present disclosure. It corresponds to the cross-sectional view along line A-A′ in FIG. 1.

In the heat-dissipating structure shown in FIG. 2, a conductive member 10, adhesive layer 42, insulating layer 60, adhesive layer 44, and cooling member 52 are disposed in this order.

Examples of the conductive member 10 include a bus bar such as a O-bus bar, an N-bus bar and a P-bus bar, and a terminal for fastening conductive members such as bus bars.

Examples of the material of the conductive member 10 include metals such as Al and Cu.

The adhesive layers 42 and 44 may be made of the same material or of different materials. The adhesive layers 42 and 44 may have the same thickness or different thicknesses.

It is sufficient that the adhesive layers 42 and 44 have adhesiveness, and the material thereof is not particularly limited. Examples of the material for the adhesive layers 42 and 44 include a resin such as a thermoplastic resin and a thermosetting resin. Examples of the thermoplastic resin include a phenoxy-type resin and an ethylene-vinyl acetate-type resin. Examples of the thermosetting resin include an epoxy-type, a silicone-type, and an acrylic-type resin.

It is preferable, from the viewpoint of manufacturing work efficiency, that the adhesive layers 42 and 44 be formed from adhesive sheets. Examples of materials for the adhesive sheet include a resin such as a phenoxy-type and an ethylene-vinyl acetate-type resin.

From the viewpoint of ensuring adhesiveness, a thickness of each of the adhesive layers 42 and 44 is preferably 5 μm or more, more preferably 10 μm or more, and still more preferably 20 μm or more. From the viewpoint of enhancing the thermal conductivity from the conductive member 10 to the cooling member 52, the thickness of each of the adhesive layers 42 and 44 is preferably 100 μm or less, more preferably 90 μm or less.

The thickness of the adhesive layers 42 and 44 can be measured with a micrometer and is an arithmetic mean value of two points.

The adhesive layers 42 and 44 may be insulating adhesive layers having insulation properties, or may have conductivity. Since the insulating layer is separately provided to achieve functional separation, the adhesive layers 42 and 44 do not necessarily have to possess insulating properties.

The insulating layer 60 may be configured to contain a resin. Examples of the resin contained in the insulating layer 60 include polyimide, polypropylene, and polyphenylene sulfide (PPS), and from the viewpoints of high heat resistance, high insulating properties, solvent resistance, and the like, polyimide is preferred.

The insulating layer 60 may be constituted of ceramics. Examples of the ceramics contained in the insulating layer 60 include conventionally known ones, for example, aluminum oxide, titanium oxide, and aluminum nitride.

From the viewpoint of ensuring insulating properties, a thickness of the insulating layer 60 is preferably 0.5 μm or more, more preferably 10 μm or more, still more preferably 20 μm or more, and particularly preferably 50 μm or more. From the viewpoint of enhancing thermal conductivity from the conductive member 10 to the cooling member 52, the thickness of the insulating layer 60 is preferably 300 μm or less, more preferably 250 μm or less, and may be 50 μm or less, and may be 40 μm or less.

The thickness of the insulating layer 60 can be measured with a micrometer and is an arithmetic mean value of two points.

From the viewpoint of ensuring insulating properties, an insulation resistance value of the insulating layer 60 is preferably 0.5×10¹⁶ Ω·cm or more, more preferably 1.0×10¹⁶ Ω·cm or more, and still more preferably 1.5×10¹⁶ Ω·cm or more. The insulation resistance value of the insulating layer 60 is preferably as high as possible.

The insulation resistance value of the insulating layer 60 can be measured with an insulation resistance meter (for example, an insulation resistance measuring instrument manufactured by Kikusui Electronics Corporation).

Examples of the cooling member 52 include a heat sink and a heat spreader. A shape of the cooling member 52 is not particularly limited.

A thermal conductivity of the cooling member 52 is preferably as high as possible, preferably 50 W/m·K or more, more preferably 90 W/m·K or more, more preferably 100 W/m·K or more, and may be 150 W/m·K or more, and may be 200 W/m·K or more. Examples of the material of the cooling member 52 include metals such as Al, Cu and Fe, and ceramics whose main material is aluminum oxide.

A distance between the conductive member 10 and the cooling and heating member 52 is preferably 500 μm or less, more preferably 450 μm or less, and still more preferably 400 μm or less. From the viewpoint of thinning, the narrower the distance between the conductive member 10 and the cooling and heating member 52, the better; however, from the viewpoint of ensuring insulation between the conductive member 10 and the cooling and heating member 52, it may be 5 nm or more, may be 10 nm or more, and may be 50 nm or more.

In a case in which, for example, three layers of an adhesive layer, an insulating layer and an adhesive layer are provided between the conductive member 10 and the cooling and heating member 52, the distance between the conductive member 10 and the cooling and heating member 52 corresponds to a total thickness of these three layers.

In the heat-dissipating structure of FIG. 2, three layers, which are an adhesive layer, an insulating layer, and an adhesive layer, are provided between the conductive member 10 and the cooling and heating member 52.

In the heat-dissipating structure of FIG. 2, in the A-A′ direction (referred to as the width direction), a length of the conductive member 10 is the same as a length of the cooling member 52, and lengths of the adhesive layers 42 and 44 and the insulating layer 60 are also aligned with the lengths of the conductive member 10 and the cooling member 52. An area of the insulating layer 60 is the same as an area of the bonding surface of the conductive member 10.

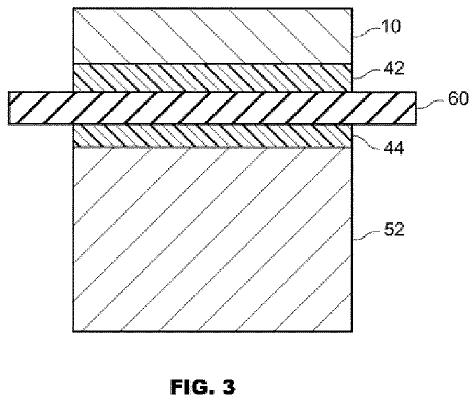

The heat-dissipating structure of FIG. 3 is a modified example of the heat-dissipating structure shown in FIG. 2, in which the length of the insulating layer 60 in the width direction is changed.

In the heat-dissipating structure of FIG. 3, a length of the adhesive layer 42 on the conductive member 10 side is the same as a length of the conductive member 10, and a length of the adhesive layer 44 on the cooling member 52 side is the same as a length of the cooling member 52. In the width direction, a length of the insulating layer 60 is longer than the lengths of the adhesive layers 42 and 44. An area of the insulating layer 60 is larger than the areas of the bonding surface of the conductive member 10 and the bonding surface of the cooling member 52. This ensures insulation more reliably.

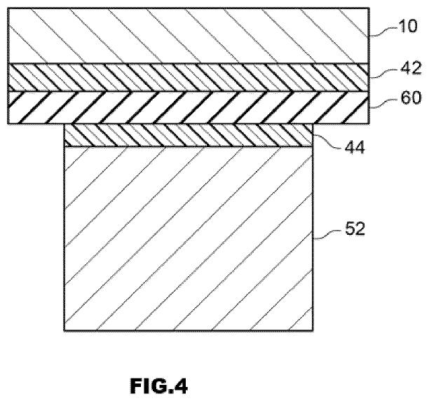

In the heat-dissipating structure of FIG. 4, in the width direction, a length of the conductive member 10 is longer than a length of the cooling member 52.

In the heat-dissipating structure of FIG. 4, a length of the adhesive layer 42 on the conductive member 10 side is the same as a length of the conductive member 10, and a length of the adhesive layer 44 on the cooling member 52 side is the same as a length of the cooling member 52. A length of the insulating layer 60 is made to be aligned with that of the adhesive layer 42, which has a greater length in the width direction among the adhesive layers 42 and 44. An area of the insulating layer 60 is larger than an area of the bonding surface of the cooling member 52. This ensures insulation more reliably.

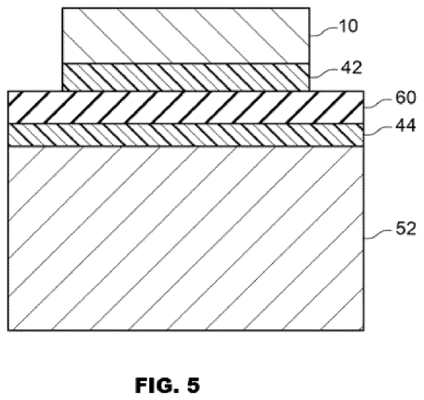

In the heat-dissipating structure of FIG. 5, in the width direction, a length of the cooling member 52 is longer than a length of the conductive member 10.

In the heat-dissipating structure of FIG. 5, a length of the adhesive layer 42 on the conductive member 10 side is the same as a length of the conductive member 10, and a length of the adhesive layer 44 on the cooling member 52 side is the same as a length of the cooling member 52. A length of the insulating layer 60 is made to be aligned with that of the adhesive layer 44, which has a greater length in the width direction among the adhesive layers 42 and 44. An area of the insulating layer 60 is larger than an area of the bonding surface of the conductive member 10. This ensures insulation more reliably.

In the heat-dissipating structure of FIG. 5, in the width direction, the length of the cooling member 52 is longer than the length of the conductive member 10. An area of the bonding surface of the cooling member 52 is larger than the area of the bonding surface of the conductive member 10. This can further enhance the cooling efficiency.

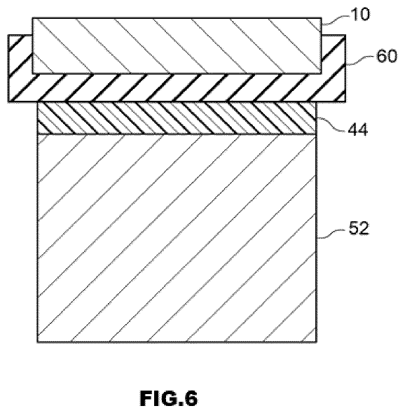

In the heat-dissipating structure of FIG. 6, an adhesive layer 42 on the conductive member 10 side is not provided, and the conductive member 10 is in contact with the insulating layer 60. Two layers, which are the insulating layer 60 and the adhesive layer 44, are provided between the conductive member 10 and the cooling and heating member 52. Thus, as compared with the heat-dissipating structures of FIGS. 2 to 5, the distance from the conductive member 10 to the cooling member 52 can be further reduced.

In the heat-dissipating structure of FIG. 6, the insulating layer 60 covers a corner portion of the conductive member 10. By the insulating layer 60 covering the corner portion of the conductive member 10, a creepage distance becomes longer, and insulation can be ensured more reliably.

The insulating layer 60, which is provided in contact with the conductive member 10 and covers a corner portion of the conductive member 10, can be formed by various methods such as electroless plating, sputtering, aerosol deposition (AD) method, atomic layer deposition (ALD) method, thermal spraying, and chemical densification. It is preferable to appropriately select these methods depending on the material to be used, the desired film thickness, and the like. For example, a film thickness can be set to from 3 μm to 20 μm in the case of electroplating, from 10 nm to 500 nm in the case of the sputtering method and the AD method, and from 10 nm to 1000 nm in the case of the ALD method.

Examples of the material of the insulating layer 60 in FIG. 6 include ceramics and the like.

In the heat-dissipating structure of FIG. 6, in the width direction, a length of the cooling member 52 is the same as a length of the conductive member 10; however, the length of the cooling member 52 may be longer than the length of the conductive member 10, or may be shorter. In a case in which the length of the cooling member 52 is longer than the length of the conductive member 10, the cooling efficiency can be further enhanced.

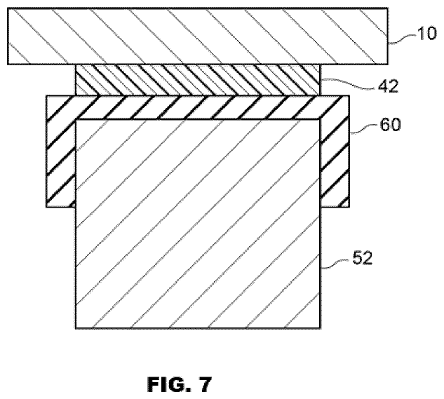

In the heat-dissipating structure of FIG. 7, an adhesive layer 44 on the cooling member 52 side is not provided, and the cooling member 52 is in contact with the insulating layer 60. Two layers, which are the adhesive layer 42 and the insulating layer 60, are provided between the conductive member 10 and the cooling and heating member 52. Thus, as compared with the heat-dissipating structures of FIGS. 2 to 5, the distance from the conductive member 10 to the cooling member 52 can be further reduced.

In the heat-dissipating structure of FIG. 7, the insulating layer 60 covers a corner portion of the cooling member 52. By the insulating layer 60 covering the corner portion of the cooling member 52, the creepage distance becomes longer, and insulation can be ensured more reliably.

The method of forming the insulating layer 60 in FIG. 7 is the same as the method of forming the insulating layer 60 in FIG. 6.

In the heat-dissipating structure of FIG. 7, in the width direction, a length of the conductive member 10 is longer than a length of the cooling member 52; however, the lengths of the conductive member 10 and the cooling member 52 may be the same, or the length of the cooling member 52 may be longer than the length of the conductive member 10, and in a case in which the length of the cooling member 52 is longer than the length of the conductive member 10, the cooling efficiency can be further enhanced.

### Additional Embodiments

The present disclosure includes the following embodiments.

<1> A heat-dissipating terminal block including: a terminal for fastening a conductive member; and a resin portion filling around the terminal,
wherein a molding shrinkage ratio of the resin portion is 1.0% or less.

<2> The heat-dissipating terminal block according to <1>, wherein a thermal conductivity of the resin portion is 0.1 W/m·K or more.

<3> The heat-dissipating terminal block according to <1> or <2>, wherein, in a case in which two or more terminals are provided, at least one of a convex portion extending outward and a concave portion recessed in the thickness direction is provided on a surface of the resin portion between the terminals.

<4> The heat-dissipating terminal block according to any one of <1> to <3>, further including an insulating adhesive layer.

<5> The heat-dissipating terminal block according to any one of <1> to <4>, further including a heat-dissipating plate.

<6> The heat-dissipating terminal block according to any one of <1> to <5>, further including an insulating layer.

The additional heat-dissipating terminal block includes a terminal for fastening a conductive member and a resin portion filling around the terminal, and a molding shrinkage ratio of the resin portion is 1.0% or less.

The reason why the additional heat-dissipating terminal block exhibits excellent heat dissipation properties is presumed to be as follows.

In JP-A No. 2016-126925, a heat sink is integrated with a resin portion; however, even in such a case, a decrease in heat dissipation may occur due to deformation of the resin portion. As a result of investigating the cause, it has been found that the deformation such as warping of the resin portion is caused by the volumetric change ratio due to curing when molding the resin portion. Due to deformation of the resin portion during molding, a gap (void) may be formed between the heat-dissipating terminal block and a heat sink or the like, and the gap hinders heat conduction, thereby reducing heat dissipation performance.

Therefore, by setting the molding shrinkage ratio of the resin portion that fills around the terminal to 1.0% or less, deformation such as warping of the resin portion is suppressed, and a reduction in the contact area between the resin portion and a heat sink disposed on the lower surface side is prevented. As a result, since heat generated from the conductive member is effectively transferred to the heat sink, it is considered that the additional heat-dissipating terminal block exhibits excellent heat dissipation performance.

Furthermore, since the additional heat-dissipating terminal block has excellent flatness on its lower surface, even when a heat sink or the like is bonded to the lower surface side of the heat-dissipating terminal block after manufacturing, the heat dissipation performance is less likely to deteriorate. Therefore, the additional heat-dissipating terminal block can be applied to various heat sinks, and its range of application is extremely wide.

In addition, the additional heat-dissipating terminal block allows the heat sink to be manufactured as a separate member. Accordingly, the additional heat-dissipating terminal block can reduce manufacturing costs because the mold for forming the resin portion is less complicated than that in Patent Document 1, and manufacturing is simplified.

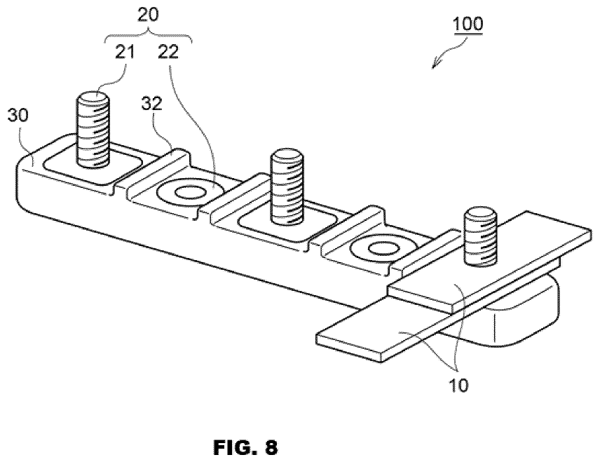

FIG. 8 is a schematic perspective view of a heat-dissipating terminal block 100 as an example of the additional heat-dissipating terminal block.

The heat-dissipating terminal block 100 has a terminal 20 for fastening a conductive member 10 such as a bus bar. From the viewpoint of thermal conductivity, it is preferable that the terminal 20 be made of a metal.

It is sufficient that the terminal 20 is capable of fastening the conductive member 10, and it may be either a bolt 21 or a nut 22. In FIG. 8, both a bolt 21 and a nut 22 are provided on the heat-dissipating terminal block 100, but only one of them may be provided. Although multiple bolts 21 and nuts 22 are provided on the heat-dissipating terminal block 100 in FIG. 8, a configuration in which a single bolt 21 or a single nut 22 is provided may also be adopted. From the viewpoint of reinforcing the strength of the heat-dissipating terminal block 100 to suppress deformation, the heat-dissipating terminal block 100 may include a reinforcing member such as a collar (not shown in FIG. 8). By providing the reinforcing member, a flatness of the lower surface side of the heat-dissipating terminal block is more reliably ensured.

The conductive member 10 may have a through-hole through which the bolt 21 passes. A plurality of conductive members 10 are stacked and placed on the bolt 21, and then the conductive members 10 are electrically connected by screwing an unillustrated nut. In a case in which the heat-dissipating terminal block 100 includes the nut 22, the conductive member 10 is fastened by screwing an unillustrated bolt into the nut 22.

A resin portion 30 is provided around the terminal 20.

A molding shrinkage ratio of the resin portion 30 is 1.0% or less, preferably 0.7% or less, more preferably 0.5% or less, still more preferably 0.3% or less, particularly preferably 0.2% or less, extremely preferably 0.1% or less, and remarkably preferably 0%.

The molding shrinkage ratio is determined by the following formula:

$$α = ( L 0 - L ) / L 0$$

in the formula, α represents the molding shrinkage ratio, L0 is a mold dimension (mm), and L is a molded product dimension (mm).

A resin contained in the resin portion 30 may be a cured product of a thermosetting resin or a thermoplastic resin. From the viewpoint of heat resistance, it is preferable that the resin portion 30 be a cured product of a thermosetting resin. By being a cured product of a thermosetting resin, the resin portion 30 exhibits excellent dimensional stability in addition to heat resistance.

Examples of the thermosetting resin include an unsaturated polyester resin, a vinyl ester-styrene resin, and a phenol resin. Examples of the thermoplastic resin include a polyethylene resin, a polypropylene resin, and a polyphenylene sulfide resin (PPS).

The resin portion 30 may contain a filler, a reinforcing material, a curing agent, a release agent, and other additives.

From the viewpoint of improving the thermal conductivity of the resin portion 30, it is preferable that the filler includes a thermally conductive particle. Examples of the thermally conductive particle include an alumina particle and a beryllium oxide particle. Examples of a filler other than the thermally conductive particle include a calcium carbonate particle, a carbon black, and a carbon fiber.

Examples of the reinforcing material include a glass fiber and an aramid fiber. The curing agent can be appropriately selected depending on the resin to be used.

A proportions of the resin, filler, reinforcing material and the like in the resin portion 30 can be adjusted as appropriate.

For example, from the viewpoint of keeping the molding shrinkage ratio of the resin portion low, a content of the resin in the resin portion 30 may be 80% by mass or less, may be 70% by mass or less, and may be 60% by mass or less. From the viewpoint of insulating properties, the content of the resin in the resin portion 30 may be 10% by mass or more, may be 30% by mass or more, and may be 50% by mass or more.

Further, a content of the filler in the resin portion 30 may be 20% by mass or more, may be 30% by mass or more, and may be 40% by mass or more. The content of the filler in the resin portion 30 may be 80% by mass or less, may be 70% by mass or less, and may be 60% by mass or less.

A content of the reinforcing material in the resin portion 30 may be 10% by mass or more, may be 20% by mass or more, and may be 30% by mass or more. The content of the reinforcing material in the resin portion 30 may be 60% by mass or less, may be 50% by mass or less, and may be 40% by mass or less.

Examples of other additives include a cure accelerator, a coupling agent, a flame retardant, a release agent, and a colorant.

As the resin composition for molding the resin portion 30, a BMC (bulk molding compound) can be used. BMC is a lump clay-like thermosetting resin composition in which various additives are added to an unsaturated polyester resin.

A thermal conductivity of the resin portion 30 is preferably 0.1 W/m·K or more, more preferably 0.3 W/m·K or more, still more preferably 0.5 W/m·K or more, particularly preferably 1.0 W/m·K or more, and extremely preferably 2.0 W/m·K or more.

The thermal conductivity of the resin portion 30 is preferably as high as possible. A method of measuring thermal conductivity is as follows.

The cured resin portion 30 obtained after curing is cut into 10 mm×10 mm to obtain a sample. After blackening the sample with a graphite spray, the thermal diffusivity is measured by the xenon flash method (product name: LFA447 nanoflash, manufactured by NETZSCH).

The thermal conductivity in the thickness direction of the resin portion 30 is determined from the product of this value, the density measured by the Archimedes method, and the specific heat measured by DSC (differential scanning calorimetry; product name: DSC Pyris1, manufactured by PerkinElmer).

In a case in which two or more terminals 20 are provided, it is preferable that a convex portion 32 extending outward be provided on a surface of the resin portion 30 between the terminals 20. In place of the convex portion 32, or together with the convex portion 32, a concave portion (not shown) recessed in the thickness direction may be provided. The convex portion 32 and the concave portion may be of the same material as the resin portion 30.

In a case in which a convex portion 32 or a concave portion is provided on the surface of the resin portion 30 between the terminals 20, the creepage distance of the resin portion 30 becomes longer, and therefore so-called creepage discharge, which occurs along the surface of the resin portion 30, is likely to be suppressed. Accordingly, by providing the convex portion 32 or the concave portion, the terminals 20 can be disposed at a narrow interval, and the heat-dissipating terminal block 100 can be made compact.

A height of the convex portion 32 and a depth of the concave portion can be appropriately designed depending on the material of the resin portion 30, a distance between the terminals 20 and the like. In a case in which a resin portion 30 tends to undergo creepage discharge, the height of the convex portion 32 is made higher and the depth of the concave portion is made deeper.

Although one convex portion 32 is provided between the terminals 20 in FIG. 8, a plurality may be provided. In a case in which a concave portion is used instead, a plurality of concave portions may also be provided.

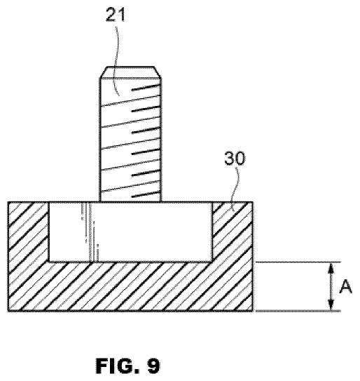

FIGS. 9 to 14 are schematic cross-sectional views around the bolt 21. In a case in which the heat-dissipating terminal block 100 includes the nut 22, the bolt 21 in FIGS. 9 to 14 can be changed to the nut 22.

As shown in FIG. 9, the resin portion 30 may be filled around the side surface and the bottom surface of the bolt 21. From the viewpoint of ensuring insulating properties, a thickness A of the resin portion 30 on the bottom surface side of the bolt 21 is preferably 0.2 mm or more, and more preferably 0.5 mm or more. From the viewpoint of enhancing thermal conductivity from the bolt 21 to a heat sink or the like, the thickness A is preferably 1.5 mm or less, and more preferably 1.0 mm or less. It should be noted that the thickness A may be less than 0.2 mm or may exceed 1.5 mm.

The thickness A of the resin portion 30 can be measured with a tool microscope and is an arithmetic mean value of two points.

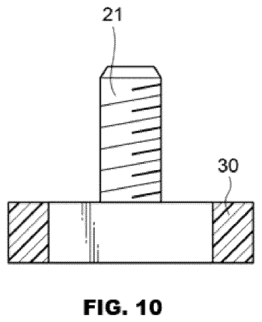

Further, as shown in FIG. 10, the bottom surface of the bolt 21 may not be filled with the resin portion 30, and the resin portion 30 may be filled around the side surface.

In the configuration of FIG. 10, since the resin portion 30 is not filled on the bottom surface side of the bolt 21, thermal conductivity is superior to that of the configuration of FIG. 9.

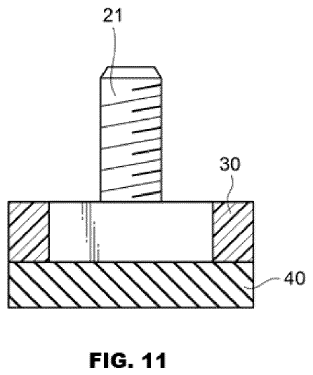

From the viewpoint of suppressing conduction from the bolt 21 to another member such as a heat sink, in the case of FIG. 10, it is preferable, as shown in FIG. 11, that an insulating adhesive layer 40 be further provided on the bottom surface of the bolt 21. Since the insulating adhesive layer 40 has adhesiveness, another member such as a heat sink can be bonded.

From the viewpoint of providing the insulating adhesive layer 40 on the bottom surface side of the bolt 21, it is preferable that the bottom surface of the bolt 21 and the lower surface of the resin portion 30 be flat and flush with each other without any step difference.

The insulating adhesive layer 40 may be configured to contain a thermoplastic resin. By the insulating adhesive layer 40 containing a thermoplastic resin, it can be bonded to another member such as a heat sink by heating.

Examples of the thermoplastic resin contained in the insulating adhesive layer 40 include a polyamide-imide, a polyimide, a fluororesin, and a polypropylene, and from the viewpoints of high heat resistance, high insulating properties, solvent resistance and the like, a polyamide-imide is preferred.

From the viewpoint of ensuring insulating properties, a thickness of the insulating adhesive layer 40 is preferably 10 μm or more, and more preferably 40 μm or more. From the viewpoint of enhancing thermal conductivity from the bolt 21 to a heat sink or the like, the thickness of the insulating adhesive layer 40 is preferably 100 μm or less, and more preferably 60 μm or less.

The thickness of the insulating adhesive layer 40 can be measured with a micrometer and is an arithmetic mean value of two points.

A dielectric breakdown voltage of the insulating adhesive layer 40 is preferably 250 V/μm or more, more preferably 300 V/μm or more, and still more preferably 400 V/μm or more.

The dielectric breakdown voltage is measured using a dielectric breakdown tester (for example, YST-243-100RHO manufactured by Yamayo Testing Machine), at a voltage ramp rate of 500 V/s, at room temperature (25° C.), in Fluorinert (manufactured by Sumitomo 3M, FC-40), and the voltage at which dielectric breakdown occurs (dielectric breakdown voltage) is obtained. The number of measurement points is twenty. The dielectric breakdown voltage is obtained by dividing by the thickness of the measured sample.

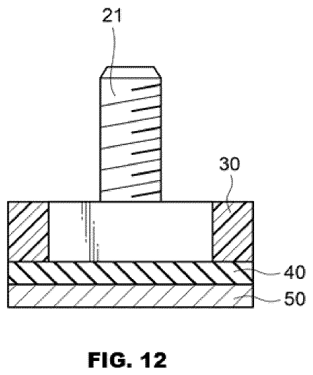

The heat-dissipating terminal block 100 may further include a heat-dissipating plate 50. In FIG. 12, the heat-dissipating plate 50 is provided on the outer surface of the insulating adhesive layer 40. In a case in which the insulating adhesive layer 40 contains a thermoplastic resin, it can be bonded to the heat-dissipating plate 50 by heating.

Examples of the heat-dissipating plate 50 include a metal plate and a ceramics plate, and specific examples thereof include an aluminum plate. The thermal conductivity of the heat-dissipating plate is preferably as high as possible, preferably 100 W/m·K or more, more preferably 150 W/m·K or more, and still more preferably 200 W/m·K or more.

From the viewpoint of ensuring heat dissipation performance, a thickness of the heat-dissipating plate 50 is preferably 1 mm or more, more preferably 2 mm or more, and still more preferably 3 mm or more. The thickness of the heat-dissipating plate 50 can be measured with a micrometer and is an arithmetic mean value of two points.

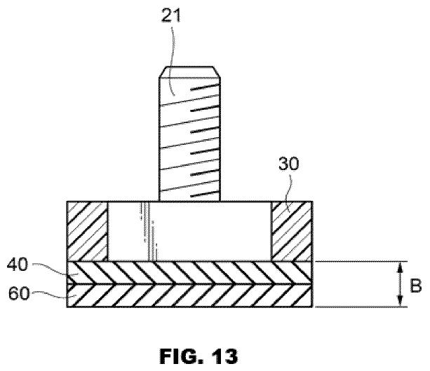

From the viewpoint of further ensuring insulation, the heat-dissipating terminal block 100 may further include an insulating layer 60. In FIG. 13, the insulating layer 60 is provided on the outer surface of the insulating adhesive layer 40.

The insulating layer 60 may be made of a material having higher insulating properties than the resin portion 30. Therefore, a total thickness B of the insulating adhesive layer 40 and the insulating layer 60, which are disposed on the bottom-surface side of the bolt 21 in the configuration shown in FIG. 6, can be designed to be thinner than a thickness A of the resin portion 30 on the bottom-surface side of the bolt 21 in the configuration shown in FIG. 9.

As the insulating layer 60 of the heat-dissipating terminal block 100, reference can be made to the insulating layer 60 described in the heat-dissipating structure in the present disclosure.

In FIG. 13, the arrangement of the insulating adhesive layer 40 and the insulating layer 60 may be interchanged. In a case in which the insulating adhesive layer 40 is provided so as to be the outer surface, the insulating adhesive layer 40 can be bonded to a heat sink or the like.

Further, the insulating adhesive layer 40 in FIG. 13 may be replaced with an adhesive layer. As the adhesive layer of the heat-dissipating terminal block 100, reference can be made to the insulating layer 60 described in the heat-dissipating structure in the present disclosure.

Although not shown in the drawings, the insulating adhesive layer 40 in FIG. 13 may be replaced with an adhesive layer, and an adhesive layer may also be provided on the outer side of the insulating layer 60. In this case, the bolt 21 serves as a conductive member 10, and an adhesive layer 42, an insulating layer 60, and an adhesive layer 44 are disposed in this order from the side of the conductive member 10, and a cooling and heating member 52 is disposed on the outer side of the adhesive layer 44. Accordingly, in this case, the heat-dissipating structure in the present disclosure shown in FIGS. 2 to 5 may be applied.

Furthermore, the arrangement of the adhesive layer and the insulating layer 60 may be interchanged. In this case, the insulating layer 60 and the adhesive layer are disposed in this order from the side surface side of the bolt 21, and the adhesive layer becomes the outer surface. In this case, the bolt 21 serves as a conductive member 10, and the insulating layer 60 and the adhesive layer 44 are provided in this order from the side of the conductive member 10, and the cooling and heating member 52 is disposed on the outer side of the adhesive layer 44. Accordingly, in this case, the heat-dissipating structure in the present disclosure shown in FIGS. 6 to 7 may be applied.

FIGS. 11 to 13 (including the case in which the insulating adhesive layer is replaced with an adhesive layer) illustrate configurations in which the insulating adhesive layer 40, the heat-dissipating plate 50, or the insulating layer 60 is further provided to the configuration of FIG. 3, in which the resin portion 30 is not filled on the bottom-surface side of the bolt 21. However, the insulating adhesive layer 40, the heat-dissipating plate 50, or the insulating layer 60 may also be further provided to the configuration of FIG. 9, in which the resin portion 30 is filled on the bottom-surface side of the bolt 21.

In the configuration of FIG. 9, in a case in which the insulating adhesive layer 40 is provided, the thickness A can be made thinner than the above range. For example, the thickness A can be 2.0 mm or less, 1.5 mm or less, or 1.0 mm or less.

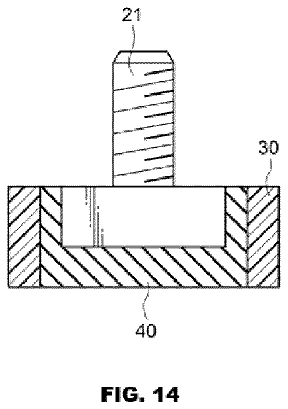

Further, as shown in FIG. 14, the insulating adhesive layer 40 may be disposed on the side surface and bottom surface of the bolt 21, and the periphery of its side surface may be filled with the resin portion 30. The insulating adhesive layer 40 may be integrally formed from the bottom surface to the side surface. Since the insulating adhesive layer 40 on the bottom-surface side is disposed as a part of the outer surface, adhesion to a heat sink or the like can be achieved by this portion of the insulating adhesive layer 40.

### <Method of Producing Heat-Dissipating Terminal Block>

The heat-dissipating terminal block in the present disclosure may be produced by insert molding in which resin is filled around the terminal. Hereinafter, a specific example of a method of producing a heat-dissipating terminal block by insert molding is shown, but the method of producing the heat-dissipating terminal block in the present disclosure is not limited to these examples.

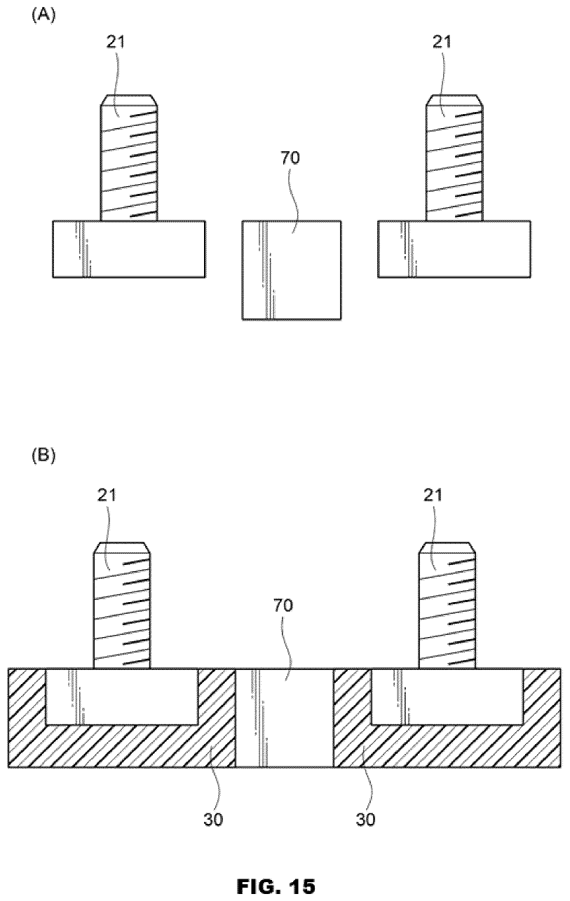

The heat-dissipating terminal block having the configuration shown in FIG. 9 is produced as shown in FIG. 15(A), by arranging the bolt 21 and, if necessary, a collar 70 serving as a reinforcing member in a mold. The bolt 21 is positioned so as not to be in contact with the lower mold, thereby allowing the resin portion 30 to be formed also on the bottom-surface side of the bolt 21.

Then, the mold is closed, a resin composition is filled, and heating is performed, thereby molding the resin portion 30 as shown in FIG. 15(B). The resin composition may be heated during filling.

The resin composition may contain, in addition to a thermosetting resin, a filler, a reinforcing material, a curing agent, a mold release agent, and other additives. The resin composition may also contain a thermoplastic resin as a resin component.

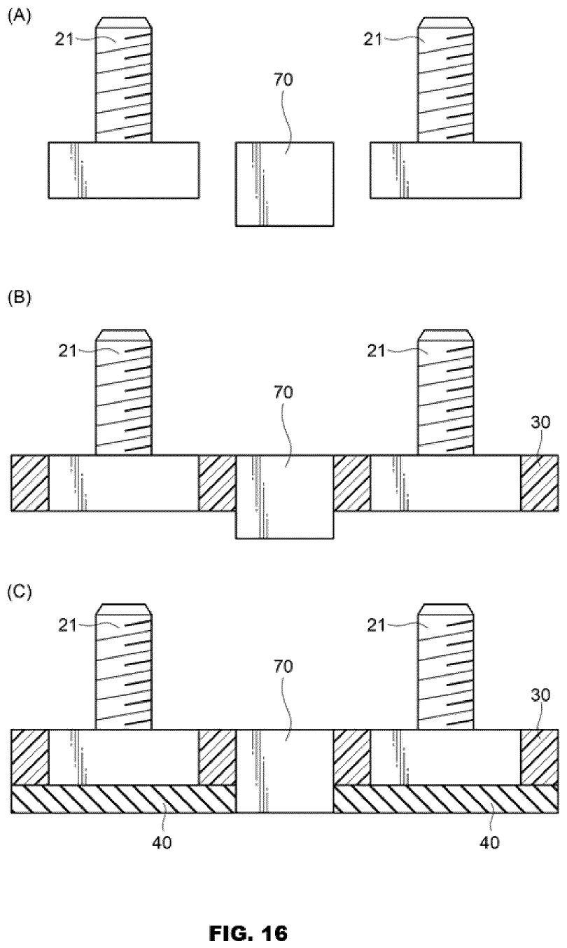

The heat-dissipating terminal block having the configuration shown in FIG. 11 is produced as shown in FIG. 16(A), by arranging the bolt 21 and, if necessary, the collar 70 in the mold. The bolt 21 is positioned so as to be in contact with the lower mold, thereby preventing the resin portion 30 from being formed on the bottom-surface side of the bolt 21. In a case in which the collar 70 is disposed, it is preferable to position the lower mold such that the distance in the thickness direction from the bottom of the collar 70 to the bottom surface of the bolt 21 becomes a thickness of the insulating adhesive layer 40 to be bonded later.

Then, the mold is closed, the resin composition is filled, and heating is performed, thereby molding the resin portion 30 as shown in FIG. 16(B).

Subsequently, the insulating adhesive layer 40 is formed on the bottom-surface side of the bolt 21. A method of forming the insulating adhesive layer 40 is not particularly limited. For example, it may be formed by spray, dispensing, spin coating, or brush coating using a coating solution containing a thermoplastic resin, or it may be formed by attaching a sheet or film containing a thermoplastic resin.

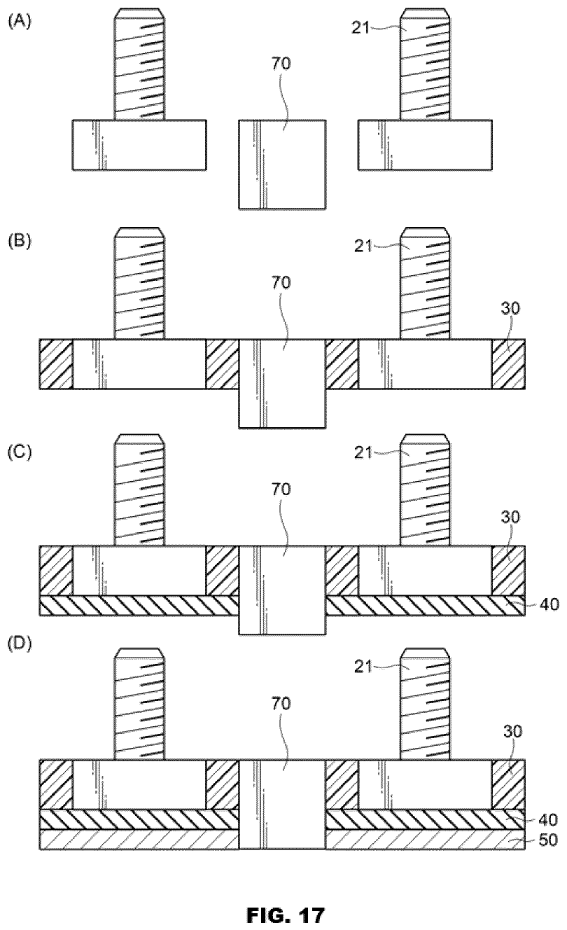

The heat-dissipating terminal block having the configuration shown in FIG. 12 is produced as shown in FIG. 17(A), by arranging the bolt 21 and, if necessary, the collar 70 in the mold. In FIG. 17(A), in a case in which the collar 70 is disposed, it is preferable to position the lower mold such that a distance in the thickness direction from the bottom of the reinforcing member to the bottom surface of the bolt 21 becomes a total thickness of the insulating adhesive layer 40 and the heat-dissipating plate 50 to be bonded later.

Then, the mold is closed, the resin composition is filled, and heating is performed, thereby molding the resin portion 30 as shown in FIG. 17(B).

Subsequently, the insulating adhesive layer 40 is formed on the bottom-surface side of the bolt 21. A method of forming the insulating adhesive layer 40 is the same as that described in FIG. 17(B). Then, a heat-dissipating plate 50 is further bonded to the outer surface of the insulating adhesive layer 40. In a case in which the insulating adhesive layer 40 contains a thermoplastic resin, the insulating adhesive layer 40 can be heated to adhere to the heat-dissipating plate 50.

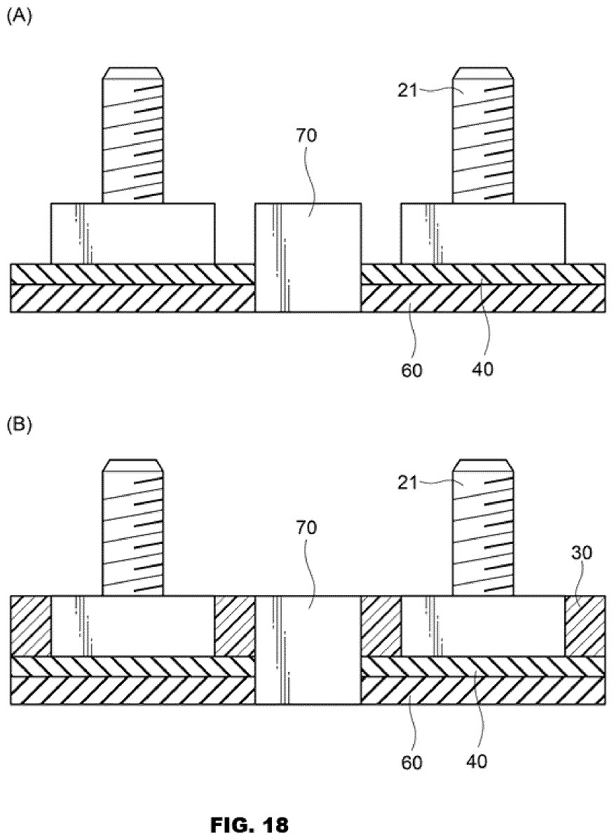

In the heat-dissipating terminal block of the configuration shown in FIG. 13, as shown in FIG. 18(A), the insulating adhesive layer 40 is provided on the insulating layer 60, and further, the bolt 21 is disposed on the insulating adhesive layer 40, and this assembly is placed inside the mold. In a case in which the collar 70 is provided, both the insulating layer 60 and the collar 70 are disposed so as to be in contact with the lower mold. In a case in which the surface of the lower mold on which the insulating layer 60 and the collar 70 are disposed is flat, the insulating layer 60 and the collar 70 are disposed flatly without any step difference.

Then, the mold is closed, the resin composition is filled, and heating is performed, thereby forming the resin portion 30 as shown in FIG. 18(B).

By disposing the insulating layer 60 on the outer side of the insulating adhesive layer 40, it is possible to prevent the insulating adhesive layer 40 from melting due to heating and adhering to the mold. Accordingly, as shown in FIG. 18, insert molding can be performed by placing the bolt 21 with the insulating adhesive layer 40 inside the mold.

The insert molding method shown in FIG. 18 can also be applied to the heat-dissipating terminal block having the configuration shown in FIG. 12. In this case, an assembly in which the heat-dissipating plate 50, the insulating adhesive layer 40, and the bolt 21 are disposed in this order is placed inside the mold, and insert molding is performed. Since the heat-dissipating plate 50 is disposed on the outer surface of the insulating adhesive layer 40, adhesion of the insulating adhesive layer 40 to the mold due to heating can be prevented.

When a convex portion 32 extending outward or a concave portion is provided on the surface of the resin portion 30 between the bolts 21, an upper mold having a concave portion or convex portion that is the reverse of the shape of the convex portion 32 or concave portion may be used. According to this method, a heat-dissipating terminal block capable of suppressing creepage discharge can be easily produced.

In FIGS. 16 to 18, the resin composition described in FIG. 15 can be used.

In FIGS. 15 to 18, the bolt 21 can be replaced with a nut 22.

Further, in FIGS. 15 to 18, the reinforcing member such as the collar 70 may or may not be disposed, and other members other than the reinforcing member may be disposed.

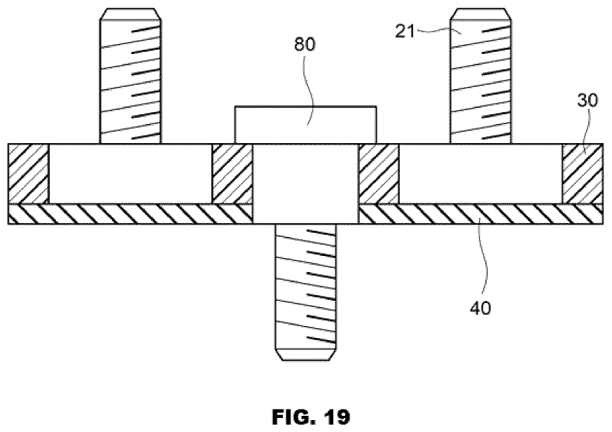

In FIGS. 15 to 18, the collar 70 is described as an example of a reinforcing member, and a shoulder bolt 80 may be used instead of the collar 70 as shown in FIG. 19. In the case of the shoulder bolt 80, since an insertion depth of the screw is fixed, the operation for ensuring flatness of the lower surface can be omitted as compared with the case of using the collar 70.

The additional heat-dissipating terminal block can be disposed in various heat sinks and the like, and can be attached, for example, to a motor case mounted on a vehicle such as an electric vehicle or a hybrid vehicle.

### EXPLANATION OF REFERENCE NUMERALS

10 Conductive member
12 O-bus bar
20 Terminal
21 Bolt
22 Nut
30 Resin portion
32 Convex portion
40 Insulating adhesive layer
42, 44 Adhesive layer
50 Heat-dissipating plate
52 Cooling and heating member
60 Insulating layer
70 Collar
80 Shoulder bolt
100 Heat-dissipating terminal block
200 Heat-dissipating structure
300 Housing

1. A heat-dissipating structure, comprising a conductive member; and a cooling and heating member,
wherein an adhesive layer and an insulating layer are provided between the conductive member and the cooling and heating member.

2. The heat-dissipating structure according to claim 1, wherein an area of the insulating layer is larger than an area of an adhesion surface of the conductive member or an area of an adhesion surface of the cooling and heating member.

3. The heat-dissipating structure according to claim 1, wherein the adhesive layer, the insulating layer, and the adhesive layer are disposed in this order from a side of the conductive member.

4. The heat-dissipating structure according to claim 1, wherein:
at least one of the conductive member or the cooling and heating member contacts the insulating layer; and
the insulating layer covers a corner portion of the at least one of the conductive member or the cooling and heating member.

5. The heat-dissipating structure according to claim 4, wherein the insulating layer and the adhesive layer are disposed in this order from a side of the conductive member.

6. The heat-dissipating structure according to claim 4, wherein the adhesive layer and the insulating layer are disposed in this order from a side of the conductive member.

7. The heat-dissipating structure according to claim 1, wherein a distance between the conductive member and the cooling and heating member is 500 μm or less.

8. The heat-dissipating structure according to claim 1, wherein the conductive member comprises at least one selected from the group consisting of a bus bar and a terminal for fastening the bus bar.

9. The heat-dissipating structure according to claim 1, wherein the adhesive layer and the insulating layer constitute a resin portion, and a molding shrinkage ratio of the resin portion is 1.0% or less.
